(19) United States
(12) Patent Application Publication
(10) Pub. No.: US 2025/0192021 A1
(43) Pub. Date: Jun. 12, 2025

(54) SEMICONDUCTOR PACKAGE

(71) Applicant: SAMSUNG ELECTRONICS CO., LTD., SUWON-SI (KR)

(72) Inventors: Junho LEE, Suwon-si (KR); Minwoo CHO, Suwon-si (KR)

(21) Appl. No.: 18/749,965

(22) Filed: Jun. 21, 2024

(30) Foreign Application Priority Data
Dec. 11, 2023 (KR) 10-2023-0178567

(51) Int. Cl. H01L 23/498; H01L 23/00; H01L 23/36

(52) U.S. Cl. CPC H01L 23/49838; H01L 23/36; H01L 24/16; H01L 23/49816; H01L 2224/16225

(57) ABSTRACT

According to an example embodiment, provided is a semiconductor package, including: a package substrate including a plurality of wiring layers and a plurality of insulating layers covering a portion of the plurality of wiring layers and a semiconductor chip mounted on the package substrate. At least a first insulating layer, among the plurality of insulating layers, comprises a first insulating member filling first and second regions and wherein a second insulating member filling a third region. The first region has a first wiring layer, among the plurality of wiring layers, and has first sides corresponding to edges of the package substrate and second sides between the first sides corresponding to corners of the package substrate. The second region is disposed between the first sides of the first region and the edges of the package substrate. The third region is disposed between the second sides of the first region and the corners of the package substrate.

### CROSS-REFERENCE TO RELATED APPLICATION(S)

This application claims under 35 U.S.C. § 119 priority to Korean Patent Application No. 10-2023-0178567 filed on Dec. 11, 2023, in the Korean Intellectual Property Office, the disclosure of which is incorporated by reference herein in its entirety.

### 1. TECHNICAL FIELD

The present disclosure relates to a semiconductor package.

### 2. DESCRIPTION OF THE RELATED ART

A semiconductor package embodies a semiconductor chip such as an integrated circuit in a form suitable for use in an electronic product. As the electronics sector has evolved, semiconductor packaging has advanced, employing heterogeneous materials stacked onto a single substrate to achieve miniaturization and weight reduction. However, this approach can trigger a warping effect in the package substrate, arising from differences in the coefficients of thermal expansion among these varied materials.

### SUMMARY

An embodiment of the present disclosure provides a semiconductor package having improved reliability.

As According to an embodiment of the present disclosure, provided is a semiconductor package including: a package substrate including a plurality of wiring layers and a plurality of insulating layers covering a portion of the plurality of wiring layers and a semiconductor chip mounted on the package substrate. At least a first insulating layer, among the plurality of insulating layers, comprises a first insulating member filling first and second regions and wherein a second insulating member filling a third region. The first region has a first wiring layer, among the plurality of wiring layers, and has first sides corresponding to edges of the package substrate and second sides between the first sides corresponding to corners of the package substrate. The second region is disposed between the first sides of the first region and the edges of the package substrate. The third region is disposed between the second sides of the first region and the corners of the package substrate.

Furthermore, according to an embodiment of the present disclosure, provided is a semiconductor package including: a package substrate including a plurality of insulating layers and a plurality of wiring layers, a semiconductor chip disposed on the package substrate and a heat dissipating member spaced apart from the semiconductor chip along a horizontal direction and disposed on the package substrate. On a plane, the package substrate has a patterned region including a central portion of the package substrate, a non-patterned region disposed around the patterned region and having a first side in contact with the patterned region, and an insulating region disposed on both sides of the non-patterned region and having a second side in contact with the patterned region and the non-patterned region. A length of a perpendicular line drawn from an adjacent apex of the package substrate to the second side is longer than a length of a perpendicular line drawn from an adjacent side surface of the package substrate to the first side.

Furthermore, according to an aspect of the present disclosure, provided is a semiconductor package including: a package substrate, a semiconductor chip disposed on the package substrate, a heat dissipating member disposed on the package substrate and surrounding the semiconductor chip. The package substrate further comprises an insulating layer, upper wiring layers disposed above the insulating layer and lower wiring layers disposed below the insulating layer and an upper insulating layer and a lower insulating layer covering the upper and lower wiring layers, respectively. One of the upper insulating layer and the lower insulating layer comprises a first portion covering the upper wiring layers or the lower wiring layers, and a second portion disposed at both ends of the first portion in a first direction and spaced apart from the upper wiring layers or the lower wiring layers disposed in the first portion in a horizontal direction. The other of the upper insulating layer and the lower insulating layer comprises a third portion covering the upper wiring layers or the lower wiring layers. A width of the first portion along the first direction is smaller than a width of the third portion along the first direction.

According to embodiments of the present disclosure, in a package substrate, by varying a ratio of copper in a wiring layer disposed in an upper region and a lower region, a warpage phenomenon may be improved, and furthermore, a semiconductor package having improved reliability may be provided.

### BRIEF DESCRIPTION OF THE DRAWINGS

The above and other features of the present disclosure will be more clearly understood from the following detailed description, taken in conjunction with the accompanying drawings, in which:

FIG. 1A is a top view illustrating a semiconductor package according to an example embodiment of the present disclosure, FIG. 1B is a cross-sectional view illustrating a cross-section taken along line I-I′ of FIG. 1A, and FIG. 1C is a plan view illustrating a cross-section taken along line II-II′ of FIG. 1B;

FIG. 2 is a cross-sectional view illustrating a semiconductor package according to an embodiment of the present disclosure;

FIG. 3 is a view illustrating a warpage shape of a semiconductor package according to a comparative example.

FIGS. 4A, 4B, 4C, 4D, 4E and 4F are cross-sectional views and plan views for each main process for explaining a method of manufacturing a semiconductor package according to an embodiment of the present disclosure.

### DETAILED DESCRIPTION OF THE EMBODIMENTS

Hereinafter, example embodiments of the present disclosure will be described with reference to the accompanying drawings. Unless otherwise specified, in the present specification, it may be understood that the expressions such as “on,” “above,” “upper,” “below”, “beneath,” “lower,” and “side,” are indicated based on the drawings, but may actually vary depending on the direction in which the components are disposed.

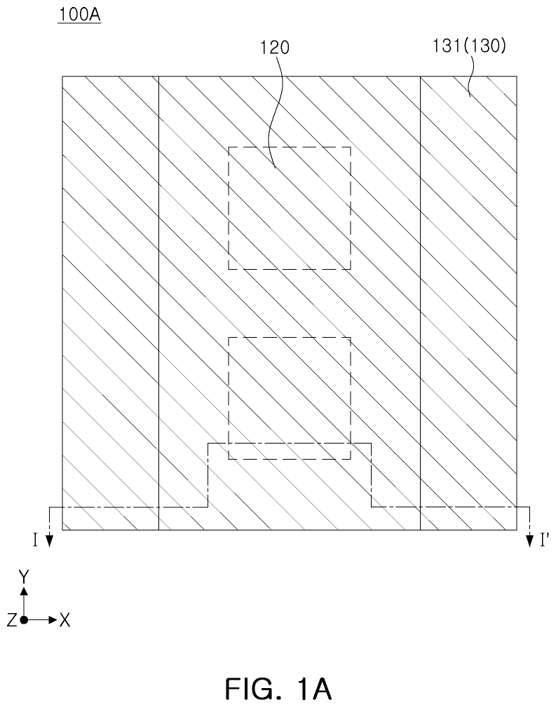

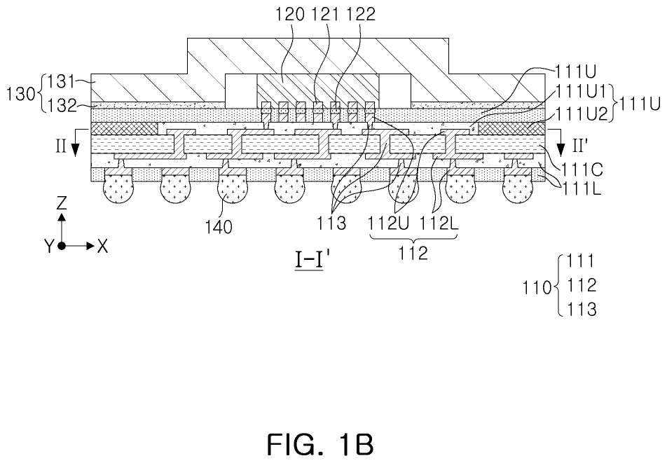

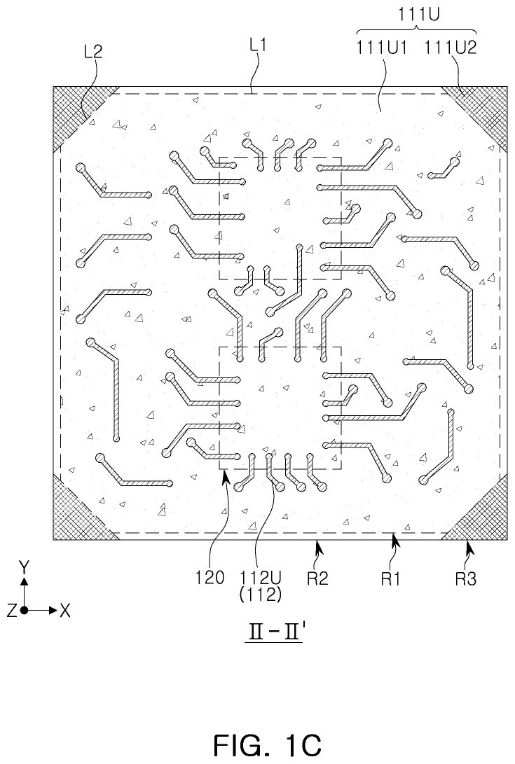

FIG. 1A is a top view illustrating a semiconductor package according to an example embodiment of the present disclosure, FIG. 1B is a cross-sectional view illustrating a cross-section taken along line I-I′ of FIG. 1A, and FIG. 1C is a plan view illustrating a cross-section taken along line II-II′ of FIG. 1B.

Referring to FIGS. 1A to 1C, a semiconductor package 100A of an embodiment may include a package substrate 110, a semiconductor chip 120, a heat dissipation member 130, and external connection conductors 140.

The package substrate 110 may be a support substrate on which the semiconductor chip 120 is mounted and may be a package substrate including a plurality of wiring layers 112 for rewiring the semiconductor chip 120. The package substrate 110 may include a printed circuit board (PCB), a ceramic board, a glass board, and a tape wiring board. For example, the package substrate 110 may include a plurality of insulating layers 111, a plurality of wiring layers 112, and a plurality of wiring vias 113.

The plurality of insulating layers 111 may include an insulating resin. The insulating resin may include a thermosetting resin such as an epoxy resin, a thermoplastic resin such as polyimide, or a resin in which inorganic fillers and/or glass fibers (Glass Fiber, Glass Cloth, or Glass Fabric) are impregnated into these resins, for example, a photosensitive resin such as prepreg, Ajinomoto Build-up Film (ABF), Flame Retardant 4 (FR-4), Bismaleimide Triazine (BT), or photoimageable dielectric (PID). An insulating layer 111 may include a plurality of insulating layers 111 stacked along a vertical direction (Z-axis direction). Depending on the process, boundaries between each of the plurality of insulating layers 111 may be unclear. For convenience of explanation, five layers of the insulating layers 111 including a core insulating layer 111C, upper insulating layers 111U disposed on the core insulating layer 111C, and lower insulating layers 111L disposed below the core insulating layer 111C are illustrated, but example embodiments of the present disclosure are not necessarily limited thereto. The core insulating layer 111C disposed in the center of the plurality of insulating layers 111, stacked between the upper insulating layers 111U and the lower insulating layer 111L, may be thicker than the insulating layers 111U and 111L. The core insulating layer 111C may improve the rigidity of the substrate and suppress warpage of the substrate. The core insulating layer 111C may be formed using, for example, a copper clad laminate (CCL), an unclad copper clad laminate (CCL), a glass substrate, or a ceramic substrate.

The plurality of wiring layers 112 may include, for example, copper (Cu), aluminum (Al), silver (Ag), tin (Sn), gold (Au), nickel (Ni), lead (Pb), and titanium (Ti), or a metallic material including alloys thereof. The wiring layers 112 may include, for example, a ground pattern, a power pattern, and a signal pattern. The signal pattern may provide a path through which various signals, such as a data signal, are transmitted/received. The wiring layers 112 may be provided as a plurality of wiring layers 112 respectively disposed on the plurality of insulating layers 111. The plurality of wiring layers 112 may be electrically connected to each other through wiring vias 113. Each of the wiring layers 112 may include a landing pad on which the semiconductor chip 120 and the external connection conductors 140 are mounted. The landing pad may be have different pitches depending on the object to be mounted. In an example, lowermost lower wiring layers 112L in contact with the external connection conductors 140 may be formed and have a greater thickness than upper lower wiring layers 112L on an upper portion thereof. Example embodiments of the present disclosure are not necessarily limited thereto and the number of layers of the lower wiring layer 112 may be determined according to the number of layers of the insulating layer 111. For example, the lower wiring layer 112 may include more or fewer layers than illustrated in the drawings. A detailed description of the plurality of insulating layers 111 and the plurality of wiring layers 112 disposed according to each region of the package substrate 110 will be described below.

The plurality of wiring vias 113 may be electrically connected to the wiring layers 112 and may include a signal via, a ground via, and a power via. The wiring vias 113 may include, for example, copper (Cu), aluminum (Al), silver (Ag), tin (Sn), gold (Au), nickel (Ni), lead (Pb), titanium (Ti), or a metallic material including alloys thereof. The wiring vias 113 may have the form of a filled via in which an interior of a via hole is filled with a metallic material, or a conformal via in which a metallic material is formed along an inner wall of the via hole. The wiring vias 113 may be integrated with the wiring layers 112, but example embodiments of the present disclosure are not necessarily limited thereto.

The package substrate 110 may have a first region R1 in which the plurality of wiring layers 112 are disposed, a second region R2 around the first region R1, and a third region R3 including at least one corner portion of the package substrate 110 and disposed adjacent to the second region R2.

The first region R1 is a region including a central portion of the package substrate 110, in a plan view, and may be a region housing upper wiring layers 112U which are disposed in a lowermost end, but the present disclosure is not necessarily limited thereto. The first region R1 may have first sides L1 corresponding to edges of the package substrate 110 and second sides L2 corresponding to corners of the package substrate 110 and disposed between the first sides L1. Excluding corner portions of the package substrate 110, the first region R1 may have an octagonal shape. An octagonal cross-section of the first region R1 may be formed by the first sides L1 and the second sides L2, and a length of the first side L1 may be longer than a length of the second side L2. The first region R1 may be a patterned region.

The second region R2 is a region arranged around the first region R1, and may be a region surrounding at least a portion of the first region R1. The second region R2 may be a region disposed between the first sides L1 of the first region R1 and the edges of the package substrate 110. The second region R2 may include at least a portion of the edges of the package substrate 110. The second region R2 may be a portion of a margin region provided with a blank space so that wiring layers adjacent to a sawing line are not damaged when the package substrate 110 in a strip substrate state is cut into units along the sawing line. The wiring layers 112 might not be disposed in the second region R2. In a plan view, sides in which the second region R2 are in contact with the first region R1 may be first sides L1. The second region R2 may be a non-patterned region.

The third region R3 is a region disposed adjacent to the second region R2 and may include at least one corner portion of the package substrate 110. The third region R3 may be a region between the second sides L2 of the first region R1 and the corners of the package substrate 110. The third region R3 may include a portion of the margin region. The third region R3 may have a shape of a right-angle triangle, on a plane. The wiring layers 112 might not be disposed in the third region R3. In a plan view, sides in which the third region R3 is in contact with the first region R1 may be second sides L2. The third region R3 may be an insulating region.

A length of a perpendicular line drawn from an adjacent apex of the package substrate 110 to the second side L2 may be longer than a length of a perpendicular line drawn from an adjacent side surface of the package substrate 110 to the first side L1. The length of the perpendicular line drawn from the adjacent apex of the package substrate 110 to the second side L2 may have a value of about 8% or less of a length of a diagonal line passing through an opposing apex of the package substrate 110, for example, in a range of about 2% to about 8%, about 4% to about 8%, about 7% to about 8%, and the like, but the present disclosure is not necessarily limited thereto.

A lowermost upper insulating layer 111U which is disposed closest to the core insulating layer 111C may include a first portion 111U1 disposed in the first and second regions R1 and R2, and a second portion 111U2 disposed in the third region R3. The first portion 111U1 may cover at least a portion of the plurality of upper wiring layers 112U in the first region R1, and the second portion 111U2 may overlap at least a portion of the plurality of lower wiring layers 112L in the third region R3 along a vertical direction (e.g., Z-axis direction). The first portion 111U1 may be disposed adjacent to the plurality of upper wiring layers 112U in the first and second regions R1 and R2, and the second portion 111U2 may be spaced apart from the plurality of upper wiring layers 112U in the third region R3. Referring to FIG. 1B, since the first portion 111U1 corresponds to a shape in which a region equivalent to the second portion 111U2 is removed from the lowermost upper insulating layer 111U, a width of the first portion 111U1 along a first direction (e.g., X-axis direction) may be smaller than a width of the uppermost lower insulating layer 111L in the first direction, and may be as small as a width of the second portion 111U2 in the first direction. The first portion 111U1 and the second portion 111U2 may include an insulating material such as an epoxy resin, prepreg, or ABF. For example, the first portion 111U1 and the second portion 111U2 may include the same insulating material and may include prepreg, but the present disclosure is not necessarily limited thereto. The first portion 111U1 and the second portion 111U2 may have the same height. The second portion 111U2 may be in contact with some of the wiring layers 112 disposed on the same level, among the wiring layers 112, along the horizontal direction (e.g., the X-axis or Y-axis direction). The first portion 111U1 may be a first insulating member, and the second portion 111U2 may be a second insulating member.

In a semiconductor package 100A of an example embodiment of the present disclosure, a ratio of the upper wiring layers 112U to the upper insulating layers 111U may be less than a ratio of the lower wiring layers 112L to the lower insulating layers 111L disposed in the third region R3 adjacent to the corner portion of the package substrate 110. Accordingly, a warpage phenomenon in the corner portion of the package substrate 110 may be prevented.

According to an example embodiment, the structural features of the present disclosure may be applied to a package substrate 110 in which a plurality of insulating layers 111 are stacked without a separate core insulating layer 111C. In a single insulating layer 111 of the plurality of insulating layers 111, when wiring layers 112 are not disposed in a region adjacent to the corner portion of the package substrate 110 (corresponding to the third region R3 in the semiconductor package ‘100A’) and an insulating member is formed, the wiring layer 112 may be different from the insulating layer 111 in upper and lower regions of the package substrate 110, thereby improving the warpage phenomenon in the corner portion in which the corresponding structure is introduced.

The semiconductor chip 120 may be mounted on the package substrate 110 and may include connection pads 121. Bump structures 122 may be spaced apart from each other at equal intervals along a first direction (e.g., X-axis direction), below the semiconductor chip 120. The bump structures 122 may electrically connect the connection pads 121 to the lower wiring layer 112. The bump structures 122 may include a metal post portion in contact with the connection pads 121 and a solder portion connecting the metal post portion and the wiring layers 112, but the present disclosure is not necessarily limited thereto. For example, the bump structures 122 may include only solder portions. A low melting point metal may include tin (Sn), indium (In), bismuth (Bi), antimony (Sb), copper (Cu), silver (Ag), zinc (Zn), lead (Pb), or alloys thereof (e.g. Sn—Ag—Cu).

The semiconductor chip 120 may include silicon (Si), germanium (Ge), or gallium arsenide (GaAs), and may have various types of integrated circuits formed therein. The integrated circuit may be a processor chip such as a central processor (e.g., CPU), a graphics processor (e.g., GPU), a field programmable gate array (FPGA), an application processor (AP), a digital signal processor, a cryptographic processor, a microprocessor, or microcontroller, but is not limited thereto, and may be a logic chip such as an analog-to-digital converter or an application-specific Integrated Circuit (IC) (ASIC), or a memory chip such as a volatile memory (e.g., Dynamic Random Access Memory (DRAM)) or a non-volatile memory (e.g., Read Only Memory (ROM) and a flash memory). According to an example embodiment, a package structure may be mounted on the package substrate 110.

The heat dissipation member 130 may be disposed on the package substrate 110 to overlap at least a portion of the semiconductor chip 120 along a vertical direction (e.g., Z-axis direction). The heat dissipation member 130 may at least partially surround the semiconductor chip 120. The heat dissipation member 130 may control warpage of the semiconductor package 100 and may radiate heat generated from the semiconductor chip 120 and the package substrate 100 to the outside.

The heat dissipation member 130 may include a thermal interface material (TIM) 131 and a heat slug 132. The thermal interface material 131 may be in contact with an upper surface 100T of a lower chip structure 100. The thermal interface material 131 may include, for example, a heat conductive adhesive tape, a heat conductive grease, and a heat conductive adhesive. The heat slug 132 may be disposed on the thermal interface material 131. The heat slug 132 may include a material having excellent thermal conductivity, such as aluminum (Al), gold (Au), silver (Ag), copper (Cu), iron (Fe), graphite, and graphene.

The external connection conductors 140 may be disposed below the package substrate 110, and may be electrically connected to the wiring layers 112. The external connection conductors 140 may physically and/or electrically connect the semiconductor package 100 to an external device. The external connection conductors 140 may include a conductive material, and may have a shape of a ball, a pin, or a lead. For example, the external connection conductors 140 may be a solder ball.

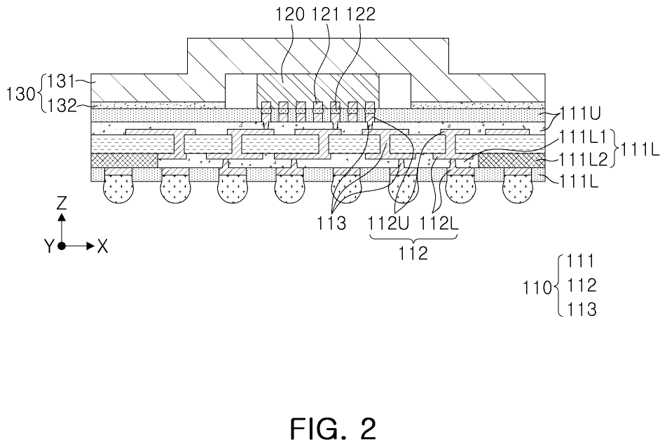

FIG. 2 is a cross-sectional view illustrating a semiconductor package 100B according to an embodiment of the present disclosure.

Referring to FIG. 2, the semiconductor package 100B of an example embodiment may have the features identical or similar to those described with reference to FIGS. 1A to 1C, except that a second portion 111L2 is included in a lower insulating layer 111L adjacent to the core insulating layer 111C. For example, the second portion 111L2 may be disposed below the core insulating layer 111C. According to an example embodiment, the second portion 111L2 disposed in the third region R3 is not necessarily limited to the upper insulating layer 111U or the lower insulating layer 111L. The second portion 111L2 may be disposed on the same level as at least one of the plurality of insulating layers 111 along the vertical direction (e.g., Z-axis direction), based on the core insulation layer 111C. According to an example embodiment, the second portion 111L2 may be disposed on the same level as two or more insulating layers 111 disposed on a lower level based on the core insulating layer 111C, but the present disclosure is not necessarily limited thereto. According to an example embodiment, in a semiconductor package 110B that does not include the core insulating layer 111C, the second portion 111L2 may be disposed in a region of an upper portion or a lower portion of the plurality of insulating layers 111. The semiconductor package 100B may prevent the warpage of the package substrate 110 due to a structure in which a ratio of the lower wiring layers 112L to the lower insulating layers 111L is greater than a ratio of the upper wiring layers 112U to the upper insulating layers 111U.

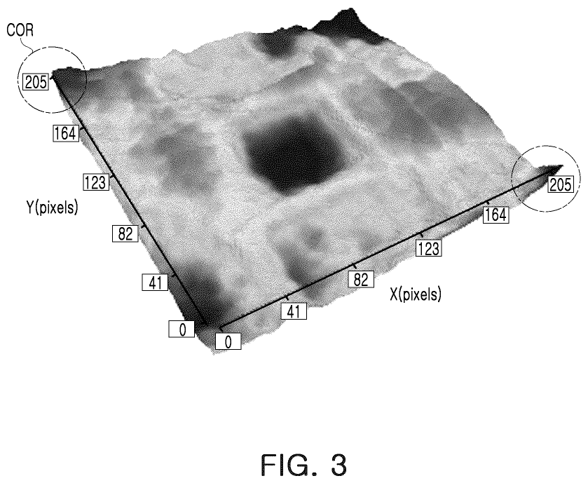

FIG. 3 is a view illustrating a warpage shape of a semiconductor package according to a comparative example.

Referring to FIG. 3, as a comparative example, a view expressing a direction of warpage that may occur in a conventional semiconductor package is illustrated. Each element constituting the semiconductor package, such as a package substrate, a semiconductor chip, and a heat dissipation member may be formed of heterogeneous materials and may have different coefficients of thermal expansion. In this case, when heat is applied during a curing process, or the like, in a semiconductor package manufacturing process, a warpage of the substrate may occur due to differences in coefficients of thermal expansion between each component. Referring to FIG. 3, it may be seen that in the substrate, the corner portion warps downwardly and the warpage may occur more severely. Referring to FIG. 3, it may be seen that in the substrate, edges (COR) opposing each other may cause the warpage in the same direction, and adjacent edges may cause the warpage in different directions. On the package substrate, as the chips are disposed asymmetrically, thermal transmission may be disproportionately performed, and accordingly, warpage at each corner portion may occur differently, which may cause twist of an entire package substrate. When a degree of warpage increases, cracks may occur at joints between respectively components in the semiconductor package, and further, reliability of the semiconductor package may be reduced.

As described above, in the semiconductor package, the warpage may occur, especially in the corner portion, due to differences in coefficients of thermal expansion between heterogeneous materials, but the present disclosure, the warping may be reduced or prevented by removing a portion of the wiring layers 112 of a specific layer near a corner of the package substrate and introducing a structure filled with an insulating member. The package substrate of the present disclosure may achieve the above-described effect by means of a structure in which the ratios of wiring layers 112 to insulating layers 111 are asymmetric, in the corner portion of the upper and lower regions thereof.

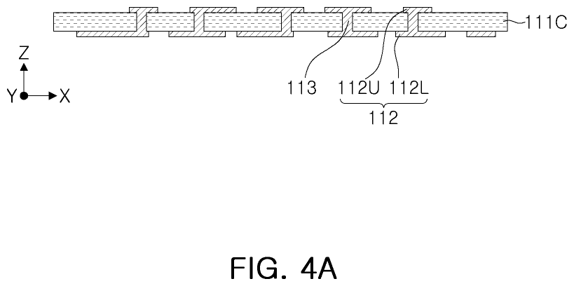

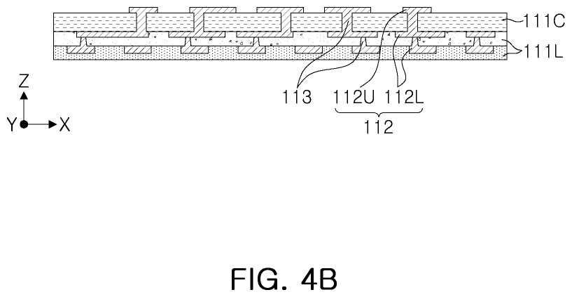

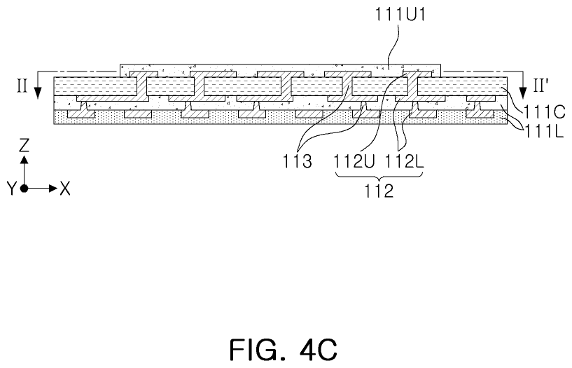

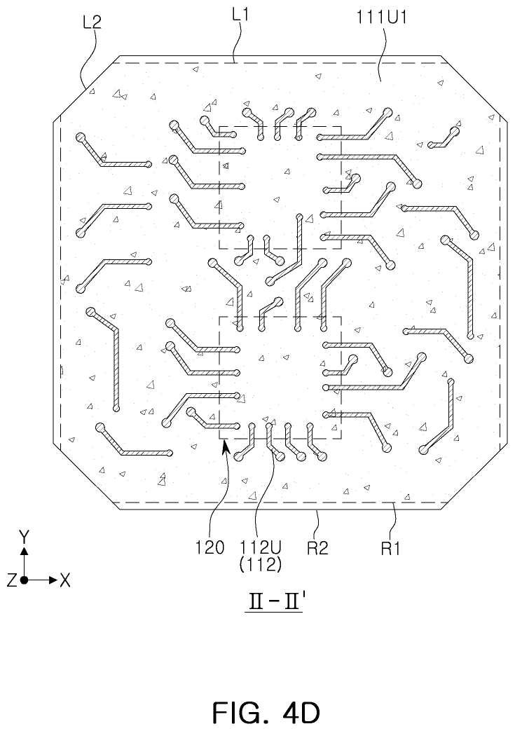

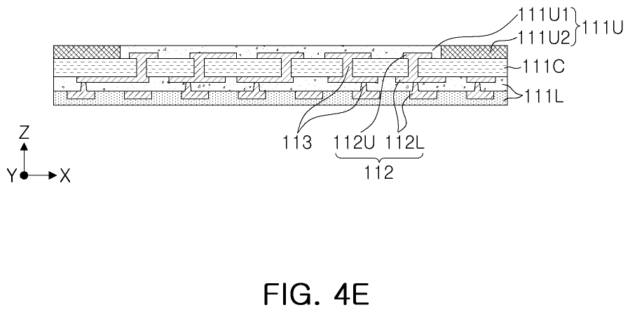

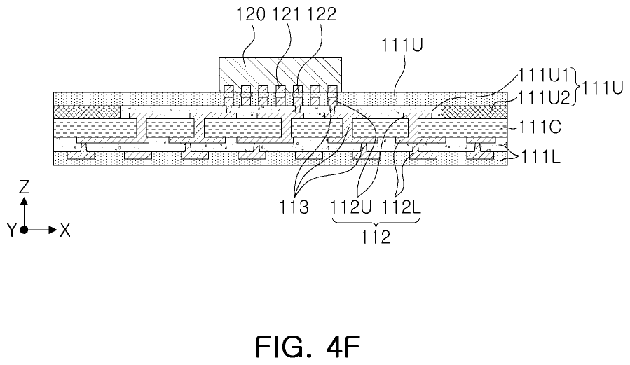

FIGS. 4A to 4F are cross-sectional views and plan views for each main process for explaining a method of manufacturing a semiconductor package according to an embodiment of the present disclosure

Referring to FIG. 4A, a core insulating layer 111C and wiring layers 112 disposed around the core insulating layer 111C may be formed.

The core insulating layer 111C may include an insulating resin, and the insulating resin may include a thermosetting resin such as an epoxy resin, a thermoplastic resin such as polyimide, or a region in which inorganic fillers and/or glass fibers (Glass Fiber, Glass Cloth, or Glass Fabric) are impregnated into these resins, for example, a photosensitive resin such as prepreg, ABF, FR-4, BT, or photoimageable dielectric (PID). The core insulating layer 111C may be formed to be thick and supplement the rigidity of the substrate.

The upper wiring layers 112U and the lower wiring layers 112L may be formed above and below the core insulating layer 111C, respectively. The wiring layers 112 may be disposed in a patterned region of the package substrate 110, and the upper wiring layers 112U might not be partially formed in a region adjacent to the corners of the package substrate 110. Wiring vias 113 penetrating through the core insulating layer 111C may be formed and connect the upper wiring layers 112U and the lower wiring layers 112L.

Referring to FIG. 4B, lower wiring layers 112L and lower insulating layers 111L disposed below the core insulating layer 111C may be formed.

The lower insulating layers 111L may form a plurality of layers. The lower insulating layers 111L may be formed and may be equal to an area of a package substrate, in a plan view. The lower wiring layers 112L may be formed below the lower wiring layers 112L as previously formed, and the wiring vias 113 may be formed to connect lower wiring layers 112L formed on different levels. The lower insulating layers 111L may be disposed to cover the lower wiring layers 112L. Referring to FIG. 4B, the lower insulating layers 111L are illustrated as two layers, but the present disclosure is not limited thereto.

Referring to FIGS. 4C and 4D, a first portion 111U1 may be formed on the core insulating layer 111C.

The first portion 111U1 may be formed in the first region R1 and the second region R2. The first portion 111U1 may have an octagonal cross-sectional shape formed by first sides L1 and second sides L2. The first sides L1 are sides corresponding to the edges of the package substrate 110 and may form the second region R2. The second sides L2 are sides corresponding to edges of a lowermost upper insulating layer 111U, and form the first region R1 in which a plurality of wiring layers 112 are disposed. The second sides L2 may be in contact with the upper wiring layers 112U and may be in contact with the lower wiring layers 112L disposed on different levels in the vertical direction (e.g., Z-axis direction), in another embodiment.

Referring to FIG. 4E, a lowermost upper insulating layer 111U may be formed by forming the second portion 111U2 adjacent to the first portion 111U1.

The first portion 111U1 and the second portion 111U2 may be formed of the same insulating material, and in an embodiment, the first portion 111U1 and the second portion 111U2 may be formed of prepreg, but the present disclosure is not limited thereto. The second portion 111U2 may be disposed in the third region R3, and a size of an area of the sum of the first portion 111U1 and the second portion 111U2 may be equal to an area of the package substrate 110, in a plan view.

Referring to FIG. 4F, the semiconductor chip 120 may be mounted on the package substrate 110 through the connection pads 121.

At least one semiconductor chip 120 may be mounted on the package substrate 110. In a plan view, the semiconductor chips 120 may be mounted to be asymmetrical to each other, and semiconductor chips 120 of different sizes may be mounted. In an example embodiment of the present disclosure, a package structure may be mounted on the package substrate 110.

Referring to FIGS. 1A to 1C, a heat dissipation member 130 surrounding at least one semiconductor chip 120 may be formed on the package substrate 110, and external connection conductors 140 connected to the lowermost wiring layers 112L may be formed below the package substrate 110, thereby forming a semiconductor package according to an example embodiment of the present disclosure.

The present disclosure is not necessarily limited to the above-described embodiments and the accompanying drawings. Therefore, those of ordinary skill in the art may make various replacements, modifications, or changes without departing from the scope of the present disclosure.

What is claimed is:

1. A semiconductor package, comprising:
a package substrate including a plurality of wiring layers and a plurality of insulating layers covering a portion of the plurality of wiring layers; and
a semiconductor chip mounted on the package substrate,
wherein at least a first insulating layer, among the plurality of insulating layers, comprises a first insulating member filling first and second regions and wherein a second insulating member filling a third region,
wherein the first region has a first wiring layer, among the plurality of wiring layers, and has first sides corresponding to edges of the package substrate and second sides between the first sides corresponding to corners of the package substrate,
wherein the second region is disposed between the first sides of the first region and the edges of the package substrate, and
wherein the third region is disposed between the second sides of the first region and the corners of the package substrate.

2. The semiconductor package of claim 1, wherein the second insulating member overlaps at least a portion of a second wiring layer on a different level from the first wiring layer along a vertical direction.

3. The semiconductor package of claim 1, wherein the second insulating member comprises prepreg.

4. The semiconductor package of claim 1, wherein the package substrate has four of the edges and four of the corners in a plan view.

5. The semiconductor package of claim 1, wherein the first insulating member covers a portion of the plurality of wiring layers.

6. The semiconductor package of claim 1, wherein a length of each of the first sides is longer than a length of each of the second sides.

7. The semiconductor package of claim 1, wherein the first region has an octagon shape formed by the first sides and the second sides in a plan view.

8. The semiconductor package of claim 1, wherein the third region has a triangular shape formed by corresponding sides of the corners of the package substrate and the edges of the package substrate in a plan view.

9. The semiconductor package of claim 1, wherein the first region and the third region are in contact with each other in a plan view.

10. The semiconductor package of claim 1, wherein the second region has a shorter length than a length of the edges of the package substrate.

11. The semiconductor package of claim 1, further comprising:
a heat dissipation member surrounding the semiconductor chip, on the package substrate.

12. A semiconductor package, comprising:
a package substrate including a plurality of insulating layers and a plurality of wiring layers;
a semiconductor chip disposed on the package substrate; and
a heat dissipating member spaced apart from the semiconductor chip along a horizontal direction and disposed on the package substrate,
wherein on a plane, the package substrate has a patterned region including a central portion of the package substrate, a non-patterned region disposed around the patterned region and having a first side in contact with the patterned region, and an insulating region disposed on both sides of the non-patterned region and having a second side in contact with the patterned region and the non-patterned region, and
wherein a length of a perpendicular line drawn from an adjacent apex of the package substrate to the second side is longer than a length of a perpendicular line drawn from an adjacent side surface of the package substrate to the first side.

13. The semiconductor package of claim 12, wherein the plurality of wiring layers overlap the second side along a vertical direction.

14. A semiconductor package comprising:
a package substrate;
a semiconductor chip disposed on the package substrate;
a heat dissipating member disposed on the package substrate and surrounding the semiconductor chip,
wherein the package substrate further comprises:
an insulating layer;
upper wiring layers disposed above the insulating layer and lower wiring layers disposed below the insulating layer; and
an upper insulating layer and a lower insulating layer covering the upper and lower wiring layers, respectively,
wherein one of the upper insulating layer and the lower insulating layer comprises a first portion covering the upper wiring layers or the lower wiring layers, and a second portion disposed at both ends of the first portion in a first direction and spaced apart from the upper wiring layers or the lower wiring layers disposed in the first portion in a horizontal direction,
wherein the other of the upper insulating layer and the lower insulating layer comprises a third portion covering the upper wiring layers or the lower wiring layers, and
wherein a width of the first portion along the first direction is smaller than a width of the third portion along the first direction.

15. The semiconductor package of claim 14, wherein the second portion overlaps the upper wiring layers or the lower wiring layers disposed in the third portion along a vertical direction.

16. The semiconductor package of claim 14, wherein the first portion and the second portion comprise the same insulating material.

17. The semiconductor package of claim 16, wherein the first portion and the second portion comprise prepreg.

18. The semiconductor package of claim 14, wherein the first portion and the second portion have the same height.

19. The semiconductor package of claim 14, wherein the upper wiring layers and the lower wiring layers comprise copper (Cu).

20. The semiconductor package of claim 19, wherein a copper ratio of the lower wiring layers to the lower insulating layers is greater than a copper ratio of the upper wiring layers to the upper insulating layers.
